(19) United States
(12) Patent Application Publication
(10) Pub. No.: US 2024/0244917 A1
(43) Pub. Date: Jul. 18, 2024

(54) DISPLAY DEVICE

(71) Applicant: Samsung Display Co., Ltd., Yongin-si (KR)

(72) Inventors: JEONGSOO KIM, Yongin-si (KR); SUK HOON KANG, Yongin-si (KR)

(21) Appl. No.: 18/487,763

(22) Filed: Oct. 16, 2023

(30) Foreign Application Priority Data
Jan. 18, 2023 (KR) 10-2023-0007441

(51) Int. Cl. H10K 59/38; H10K 59/122

(52) U.S. Cl. CPC H10K 59/38; H10K 59/122; H10K 59/351

(57) ABSTRACT

A display device includes a first base substrate, a second base substrate facing the first base substrate, a first light-emitting element above the first base substrate, a second light-emitting element above the first base substrate, a third light-emitting element above the first base substrate, a pixel-defining layer above the first base substrate, and between the second light-emitting element and the third light-emitting element, a bank layer under the second base substrate, and defining a first opening overlapping the first light-emitting element, and a second opening overlapping the second light-emitting element, the third light-emitting element, and the pixel-defining layer, and a transmission layer inside the second opening.

### CROSS-REFERENCE TO RELATED APPLICATION(S)

This application claims priority to, and the benefit of, Korean Patent Application No. 10-2023-0007441, filed on Jan. 18, 2023, in the Korean Intellectual Property Office (KIPO), the entire contents of which are incorporated herein by reference.

### BACKGROUND

### 1. Field

Embodiments relate to a display device.

### 2. Description of the Related Art

The display device is a device that displays an image for providing visual information to a user. Among display devices, an organic light-emitting diode display has recently attracted attention.

Recently, to improve display quality, a display unit including a plurality of pixels, and a color filter unit including a color filter layer and a color conversion layer, have been proposed. The color conversion layer may convert a wavelength of light provided by the display unit. Accordingly, the display device including the color conversion layer may emit light having a color that is different from a color of incident light. For example, the color conversion layer may include wavelength conversion particles, such as quantum dots.

### SUMMARY

Embodiments provide a display device with improved reflection color separation.

A display device according to one or more embodiments includes a first base substrate, a second base substrate facing the first base substrate, a first light-emitting element above the first base substrate, a second light-emitting element above the first base substrate, a third light-emitting element above the first base substrate, a pixel-defining layer above the first base substrate, and between the second light-emitting element and the third light-emitting element, a bank layer under the second base substrate, and defining a first opening overlapping the first light-emitting element, and a second opening overlapping the second light-emitting element, the third light-emitting element, and the pixel-defining layer, and a transmission layer inside the second opening.

The display device may further include a black matrix layer between the second base substrate and the bank layer, and defining a first cutout portion, a second cutout portion, and a third cutout portion overlapping the first light-emitting element, the second light-emitting element, and the third light-emitting element, respectively.

A width of the first cutout portion may be greater than a width of the second cutout portion and a width of the third cutout portion.

The first cutout portion, the second cutout portion, and the third cutout portion may have a rectangular shape in a plan view.

The display device may further include a color filter layer including a first color filter and a second color filter between the second base substrate and the bank layer.

The second color filter may overlap the second opening, and may be configured to transmit blue light.

A width of the first light-emitting element may be greater than a width of the second light-emitting element and a width of the third light-emitting element.

A distance between the first light-emitting element and the second light-emitting element may be greater than a distance between the second light-emitting element and the third light-emitting element.

The first opening and the second opening may have a rectangular shape in a plan view.

The display device may further include a color conversion layer including scatterer and wavelength conversion particle filling the first opening.

A display device according to one or more other embodiments includes a first base substrate, a second base substrate facing the first base substrate, a first light-emitting element above the first base substrate, a second light-emitting element above the first base substrate, and spaced apart from the first light-emitting element in a first direction, a third light-emitting element above the first base substrate, and spaced apart from the second light-emitting element in a second direction crossing the first direction, a pixel-defining layer above the first base substrate, and between the second light-emitting element and the third light-emitting element, a bank layer under the second base substrate, and defining a first opening overlapping the first light-emitting element, and a second opening overlapping the second light-emitting element, the third light-emitting element, and the pixel-defining layer, and a transmission layer inside the second opening.

The display device may further include a black matrix layer between the second base substrate and the bank layer, and defining a first cutout portion, a second cutout portion, and a third cutout portion overlapping the first light-emitting element, the second light-emitting element, and the third light-emitting element, respectively.

A width of the first cutout portion in the second direction may be greater than a width of the second cutout portion in the second direction and a width of the third cutout portion in the second direction.

The first cutout portion, the second cutout portion, and the third cutout portion may have a rectangular shape in a plan view.

The display device may further include a color filter layer including a first color filter and a second color filter between the second base substrate and the bank layer.

The second color filter may overlap the second opening, and may be configured to transmit blue light.

A width of the first light-emitting element may be greater than a width of the second light-emitting element and a width of the third light-emitting element.

A distance between the first light-emitting element and the second light-emitting element may be greater than a distance between the second light-emitting element and the third light-emitting element.

The first opening and the second opening may have a rectangular shape in a plan view.

The display device may further include a color conversion layer including scatterer and wavelength conversion particle filling the first opening.

A color conversion layer (or a transmission layer) may be formed through an inkjet process in an opening defined in a bank layer. To proceed with the inkjet process, the opening must be sufficiently large. Accordingly, there may be a limit to narrowing gap between pixels. That is, there may be a limit to improving resolution of a display device.

A display device according to one or more embodiments includes a first base substrate, a second base substrate facing the first base substrate, a first light emitting element on the first base substrate, a second light emitting element on the first base substrate, a third light emitting element on the first base substrate, a pixel defining layer on the first base substrate and between the second light emitting element and the third light emitting element, a bank layer under the second base substrate and defining a first opening overlapping the first light emitting element and a second opening overlapping the second light emitting element, the third light emitting element, and the pixel defining layer, and a transmission layer inside the second opening.

Accordingly, adjacent light-emitting elements may be located in one opening defined in the bank layer. Accordingly, a distance between adjacent pixel areas may be narrowed. Accordingly, the resolution of the display device may be improved.

### BRIEF DESCRIPTION OF THE DRAWINGS

Illustrative, non-limiting embodiments will be more clearly understood from the following detailed description in conjunction with the accompanying drawings.

FIG. 1 is a schematic plan view illustrating a display device according to one or more embodiments.

FIG. 2 is a schematic cross-sectional view of the display device of FIG. 1 cut along the line I-I′.

FIG. 3 is a schematic plan view illustrating a bank layer included in the display device of FIG. 1.

FIG. 4 is a schematic plan view illustrating a black matrix layer included in the display device of FIG. 1.

FIG. 5 is a schematic plan view illustrating a bank layer included in a display device according to one or more other embodiments.

FIG. 6 is a schematic plan view illustrating a black matrix layer included in the display device according to one or more other embodiments.

FIG. 7 is a schematic cross-sectional view illustrating a display device according to one or more other embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The present disclosure covers all modifications, equivalents, and replacements within the idea and technical scope of the present disclosure. Further, each of the features of the various embodiments of the present disclosure may be combined or combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. In other instances, well-known structures and devices are shown in block diagram form to avoid unnecessarily obscuring various embodiments.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression such as “at least one of A and B” and “at least one of A or B” may include A, B, or A and B. As used herein, “or” generally means “and/or,” and the term “and/or” includes any and all combinations of one or more of the associated listed items. For example, the expression such as “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

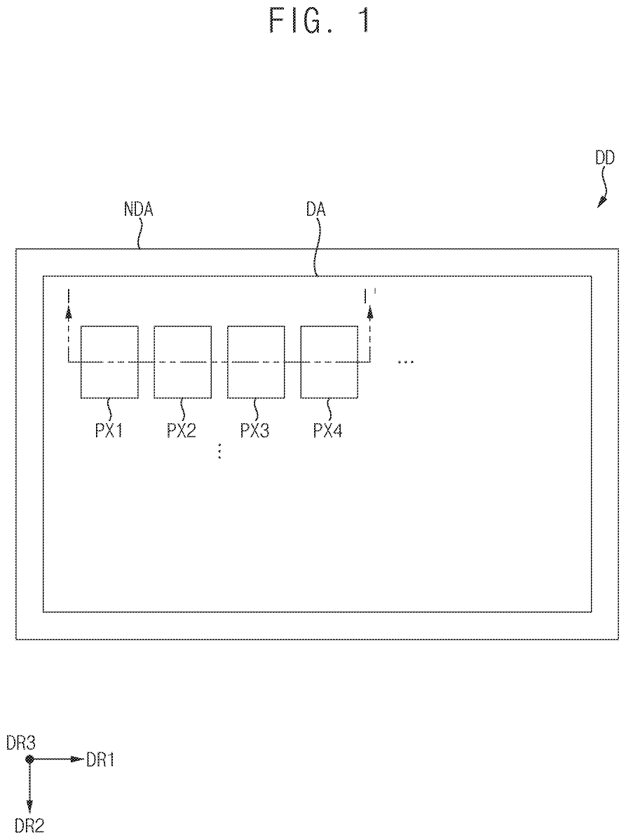

FIG. 1 is a schematic plan view illustrating a display device according to one or more embodiments.

Referring to FIG. 1, a display device DD according to one or more embodiments may include a display area DA and a non-display area NDA. The display area DA may be defined as an area for emitting light. The non-display area NDA may be defined as an area in which configurations for transmitting a signal to the display area DA are located.

A plurality of pixel areas may be located in the display area DA. For example, the plurality of pixel areas may include a first pixel area PX1, a second pixel area PX2, a third pixel area PX3, and a fourth pixel area PX4. Each of the first pixel area PX1, the second pixel area PX2, the third pixel area PX3, and the fourth pixel area PX4 may refer to an area in which light emitted from light-emitting elements is emitted to outside of the display device DD.

The plurality of pixel areas may be repeatedly arranged along a first direction DR1, and along a second direction DR2 crossing the first direction DR1 on a plane. For example, the second pixel area PX2 may be spaced apart from the first pixel area PX1. For example, the second pixel area PX2 may be spaced apart from the first pixel area PX1 in a first direction DR1.

The non-display area NDA may be located around the display area DA (e.g., in plan view). For example, the non-display area NDA may surround at least a portion of the display area DA. A driver may be located in the non-display area NDA. The driver may provide a signal or a voltage to the plurality of pixel areas. For example, the driver may include a data driver, a gate driver, or the like. The non-display area NDA may not display an image.

The first direction DR1 and the second direction DR2 crossing the first direction DR1 may be defined. A third direction DR3 perpendicular to a plane formed by the first direction DR1 and the second direction DR2 may be defined.

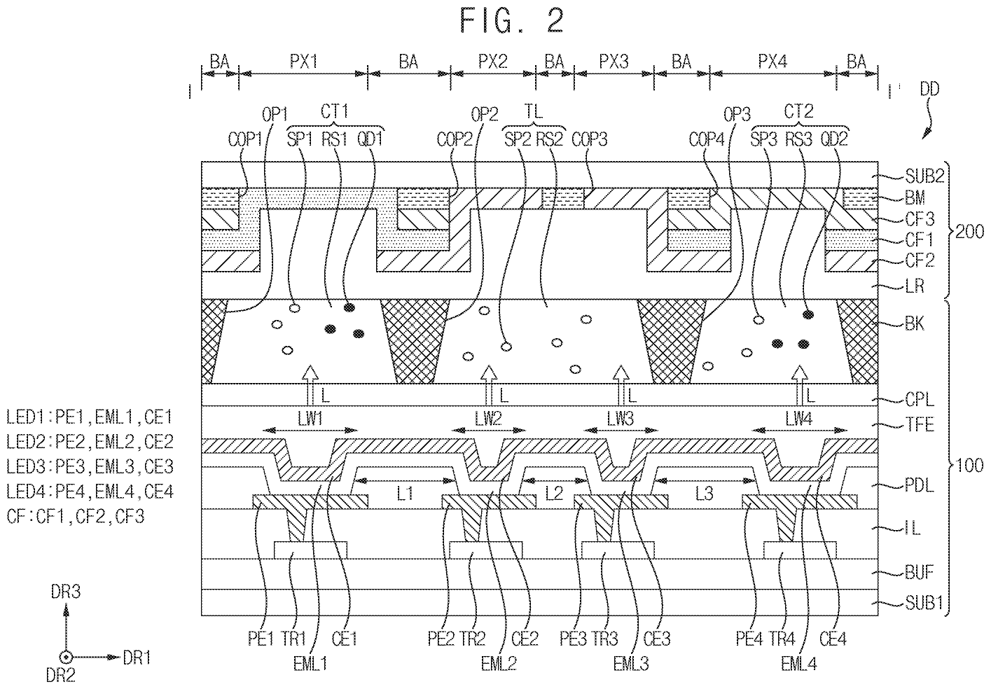

FIG. 2 is a schematic cross-sectional view of the display device of FIG. 1 cut along the line I-I′.

Referring to FIG. 2, the display device DD according to one or more embodiments may include a display 100 and a color filter (e.g., color filter unit) 200.

The display 100 may include a first base substrate SUB1, a buffer layer BUF, an insulating layer IL, a pixel-defining layer PDL, an encapsulation layer TFE, a first pixel electrode PE1, a first light-emitting layer EML1, a first common electrode CE1, a second pixel electrode PE2, a second light-emitting layer EML2, a second common electrode CE2, a third pixel electrode PE3, a third light-emitting layer EML3, a third common electrode CE3, a fourth pixel electrode PE4, a fourth light-emitting layer EML4, a fourth common electrode CE4, a first transistor TR1, a second transistor TR2, a third transistor TR3, and a fourth transistor TR4.

The first transistor TR1 may include a first active pattern, a first gate electrode, a first source electrode, and a first drain electrode. The second transistor TR2 may include a second active pattern, a second gate electrode, a second source electrode, and a second drain electrode. The third transistor TR3 may include a third active pattern, a third gate electrode, a third source electrode, and a third drain electrode. The fourth transistor TR4 may include a fourth active pattern, a fourth gate electrode, a fourth source electrode, and a fourth drain electrode.

The first base substrate SUB1 may include a transparent material or an opaque material. The first base substrate SUB1 may be formed of a transparent resin substrate. Examples of the transparent resin substrate may include a polyimide substrate. In this case, the polyimide substrate may include a first organic layer, a first barrier layer, a second organic layer, or the like.

Alternatively, the first base substrate SUB1 may include a quartz substrate, a synthetic quartz substrate, a calcium fluoride substrate, a fluorine-doped quartz substrate, a soda lime glass substrate, a non-alkali glass substrate, and/or the like. These materials may be used alone or in combination with each other.

The buffer layer BUF may be located on (e.g., above) the first base substrate SUB1. The buffer layer BUF may reduce or prevent metal atoms or impurities diffusing from the first base substrate SUB1 to the first transistor TR1, the second transistor TR2, the third transistor TR3, and the fourth transistor TR4. The buffer layer BUF may improve flatness of a surface of the first base substrate SUB1 if the surface of the first base substrate SUB1 is not uniform.

For example, the buffer layer BUF may include an inorganic material, such as silicon oxide, silicon nitride, silicon oxynitride, or the like. These materials may be used alone or in combination with each other.

The first transistor TR1, the second transistor TR2, the third transistor TR3, and the fourth transistor TR4 may be located on (e.g., above) the buffer layer BUF. For example, each of the first transistor TR1, the second transistor TR2, the third transistor TR3, and the fourth transistor TR4 may include polycrystalline silicon or metal oxide semiconductor.

The metal oxide semiconductor may include a binary compound (ABₓ), a ternary compound (ABₓC_{y}), a tetragonal compound (ABₓC_{y}D_{z}), or the like containing indium (In), zinc (Zn), gallium (Ga), tin (Sn), titanium (Ti), aluminum (Al), hafnium (Hf), zirconium (Zr), magnesium (Mg), or the like.

For example, the metal oxide semiconductor may include zinc oxide (ZnOₓ), gallium oxide (GaOₓ), tin oxide (SnOₓ), indium oxide (InOₓ), indium gallium oxide (IGO), indium zinc oxide (IZO), indium tin oxide (ITO), indium zinc tin oxide (IZTO), indium gallium zinc oxide (IGZO), or the like. These materials may be used alone or in combination with each other.

The insulating layer IL may be located on (e.g., above) the buffer layer BUF. The insulating layer IL may cover the first transistor TR1, the second transistor TR2, the third transistor TR3, and the fourth transistor TR4. The insulating layer IL may include at least one inorganic insulating layer and at least one organic insulating layer.

For example, the inorganic insulating layer may include silicon oxide (SiOₓ), silicon nitride (SiNₓ), silicon carbide (SiCₓ), silicon oxynitride (SiOₓN_{y}), silicon oxycarbide (SiOₓC_{y}), or the like. These materials may be used alone or in combination with each other.

The organic insulating layer may include photoresist, polyacryl-based resin, polyimide-based resin, polyamide-based resin, siloxane-based resin, acrylic-based resin, epoxy-based resin, or the like. These materials may be used alone or in combination with each other.

The first pixel electrode PE1, the second pixel electrode PE2, the third pixel electrode PE3, and the fourth pixel electrode PE4 may be located on (e.g., above) the insulating layer IL. The first pixel electrode PE1 may overlap the first pixel area PX1. The second pixel electrode PE2 may overlap the second pixel area PX2. The third pixel electrode PE3 may overlap the third pixel area PX3. The fourth pixel electrode PE4 may overlap the fourth pixel area PX4.

The first pixel electrode PE1 may be connected to the first transistor TR1 through a first contact hole formed by removing a portion of the insulating layer IL. The second pixel electrode PE2 may be connected to the second transistor TR2 through a second contact hole formed by removing a portion of the insulating layer IL. The third pixel electrode PE3 may be connected to the third transistor TR3 through a third contact hole formed by removing a portion of the insulating layer IL. The fourth pixel electrode PE4 may be connected to the fourth transistor TR4 through a fourth contact hole formed by removing a portion of the insulating layer IL.

For example, each of the first pixel electrode PE1, the second pixel electrode PE2, the third pixel electrode PE3, and the fourth pixel electrode PE4 may include a metal, an alloy, a metal nitride, a conductive metal oxide, a transparent conductive material, or the like. These materials may be used alone or in combination with each other. For example, each of the first pixel electrode PE1, the second pixel electrode PE2, the third pixel electrode PE3, and the fourth pixel electrode PE4 may operate as an anode.

The pixel-defining layer PDL may be located on (e.g., above) the insulating layer IL, the first pixel electrode PE1, the second pixel electrode PE2, the third pixel electrode PE3, and the fourth pixel electrode PE4. The pixel-defining layer PDL may overlap a non-light-emitting area BA.

The pixel-defining layer PDL may cover both side portions of each of the first pixel electrode PE1, the second pixel electrode PE2, the third pixel electrode PE3, and the fourth pixel electrode PE4, and may expose an upper surface of each of the first pixel electrode PE1, the second pixel electrode PE2, the third pixel electrode PE3, and the fourth pixel electrode PE4.

The pixel-defining layer PDL may include an organic material and/or an inorganic material. In one or more embodiments, the pixel-defining layer PDL may include an organic material. For example, the pixel-defining layer PDL may include photoresist, polyacrylic resin, polyimide resin, polyamide resin, siloxane resin, acrylic resin, epoxy resin, or the like. These materials may be used alone or in combination with each other.

A light-emitting layer may be located on (e.g., above) the first pixel electrode PE1, the second pixel electrode PE2, the third pixel electrode PE3, the fourth pixel electrode PE4 and the pixel-defining layer PDL. In one or more embodiments, the light-emitting layer may be continuously located over the first pixel area PX1, the second pixel area PX2, the third pixel area PX3, the fourth pixel area PX4, and the non-light-emitting area BA. However, the present disclosure is not limited thereto, and in one or more other embodiments, individual light-emitting layers may be respectively located in the first pixel area PX1, the second pixel area PX2, the third pixel area PX3, and the fourth pixel area PX4 and may not be located in the non-light-emitting area BA.

For example, the light-emitting layer may include the first light-emitting layer EML1, the second light-emitting layer EML2, the third light-emitting layer EML3, and the fourth light-emitting layer EML4. The first light-emitting layer EML1 may overlap the first pixel area PX1. The second light-emitting layer EML2 may overlap the second pixel area PX2. The third light-emitting layer EML3 may overlap the third pixel area PX3. The fourth light-emitting layer EML4 may overlap the fourth pixel area PX4.

Holes provided from the first pixel electrode PE1, and electrons provided from the first common electrode CE1, may be combined in the first light-emitting layer EML1 to form a first exciton. Holes provided by the second pixel electrode PE2, and the electrons provided by the second common electrode CE2, may be combined in the second light-emitting layer EML2 to form a second exciton. Holes provided by the third pixel electrode PE3, and electrons provided by the third common electrode CE3, may be combined in the third light-emitting layer EML3 to form a third exciton. Holes provided by the fourth pixel electrode PE4, and electrons provided by the fourth common electrode CE4, may be combined in the fourth light-emitting layer EML4 to form a fourth exciton.

As the first exciton changes from an excitation state to a ground state, the first light-emitting layer EML1 may emit light. As the second exciton changes from an excitation state to a ground state, the second light-emitting layer EML2 may emit light. As the third exciton changes from an excitation state to a ground state, the third light-emitting layer EML3 may emit light. As the fourth exciton changes from an excitation state to a ground state, the fourth light-emitting layer EML4 may emit light.

A common electrode may be located on (e.g., above) the light-emitting layer. In one or more embodiments, the common electrode may be continuously located over the first pixel area PX1, the second pixel area PX2, the third pixel area PX3, the fourth pixel area PX4, and the non-light-emitting area BA.

The common electrode may include the first common electrode CE1, the second common electrode CE2, the third common electrode CE3, and the fourth common electrode CE4. The first common electrode CE1 may overlap the first pixel area PX1. The second common electrode CE2 may overlap the second pixel area PX2. The third common electrode CE3 may overlap the third pixel area PX3. The fourth common electrode CE4 may overlap the fourth pixel area PX4.

For example, each of the first common electrode CE1, the second common electrode CE2, the third common electrode CE3, and the fourth common electrode CE4 may include a metal, an alloy, a metal nitride, a conductive metal oxide, a transparent conductive material, or the like. These materials may be used alone or in combination with each other. For example, each of the first common electrode CE1, the second common electrode CE2, the third common electrode CE3, and the fourth common electrode CE4 may operate as a cathode.

The first pixel electrode PE1, the first light-emitting layer EML1, and the first common electrode CE1 may constitute a first light-emitting element LED1. The second pixel electrode PE2, the second light-emitting layer EML2, and the second common electrode CE2 may constitute a second light-emitting element LED2. The third pixel electrode PE3, the third light-emitting layer EML3, and the third common electrode CE3 may constitute a third light-emitting element LED3. The fourth pixel electrode PE4, the fourth light-emitting layer EML4, and the fourth common electrode CE4 may constitute a fourth light-emitting element LED4.

The encapsulation layer TFE may be located on (e.g., above) the first common electrode CE1, the second common electrode CE2, the third common electrode CE3, and the fourth common electrode CE4. The encapsulation layer TFE may reduce or prevent penetration of impurities, moisture, and the like into each of the first light-emitting element LED1, the second light-emitting element LED2, the third light-emitting element LED3, and the fourth light-emitting element LED4 from the outside.

The encapsulation layer TFE may include at least one inorganic encapsulation layer and at least one organic encapsulation layer. For example, the inorganic encapsulation layer may include silicon oxide, silicon nitride, silicon oxynitride, or the like, and the organic encapsulation layer may include a polymer cured product, such as polyacrylate.

The capping layer CPL may be located on (e.g., above) the encapsulation layer TFE. In one or more embodiments, the capping layer CPL may include an inorganic material. Examples of the inorganic material that may be used as the capping layer CPL may include silicon oxide, silicon nitride, or the like. These materials may be used alone or in combination with each other.

The bank layer BK may be located on (e.g., above) the capping layer CPL. The bank layer BK may define a first opening OP1 in a portion overlapping the first pixel area PX1. That is, the bank layer BK may define the first opening OP1 in a portion overlapping the first light-emitting element LED1.

The bank layer BK may define a second opening OP2 in a portion overlapping the second pixel area PX2, the third pixel area PX3, and the non-light-emitting area BA. The non-light-emitting area BA may be located between the second pixel area PX2 and the third pixel area PX3. That is, the bank layer BK may define the second opening OP2 in a portion overlapping the second light-emitting element LED2, the third light-emitting element LED3, and the pixel-defining layer PDL. The pixel-defining layer PDL may be located between the second light-emitting element LED2 and the third light-emitting element LED3.

The bank layer BK may define a third opening OP3 in a portion overlapping the fourth pixel area PX4. That is, the bank layer BK may define the third opening OP3 in a portion overlapping the fourth light-emitting element LED4.

The bank layer BK may reduce or prevent color mixing between adjacent pixel areas. In one or more embodiments, the bank layer BK may include an organic material. In one or more embodiments, the bank layer BK may include a light-blocking material. For example, the bank layer BK may include a black pigment, a black dye, carbon black, or the like. These materials may be used alone or in combination with each other.

In one or more embodiments, the bank layer BK may include a scatterer. The scatterer may include titanium dioxide (TiO₂), silicon dioxide (SiO₂), barium sulfate (BaSO₄), aluminum oxide (Al₂O₃), zinc oxide (ZnO), zirconium dioxide (ZrO₂), or the like. These materials may be used alone or in combination with each other.

A first color conversion layer CT1 may be located inside the first opening OP1. That is, the first color conversion layer CT1 may overlap the first pixel area PX1. For example, the first color conversion layer CT1 may include a first resin part RS1, a first scatterer SP1, and a first wavelength conversion particle QD1. In one or more embodiments, the first color conversion layer CT1 may be formed through an inkjet process.

For example, the first resin part RS1 may include an epoxy-based resin, an acrylic resin, a phenol-based resin, a melamine-based resin, a cardo-based resin, an imide-based resin, or the like. These materials may be used alone or in combination with each other.

The first scatterer SP1 may increase light path by scattering incident light L without substantially converting a wavelength of the incident light L incident on the first color conversion layer CT1. In one or more embodiments, the first scatterer SP1 may include a metal oxide or an organic material. In one or more embodiments, the first scatterer SP1 may include titanium dioxide (TiO₂).

The first wavelength conversion particle QD1 may include quantum dot. The quantum dot may absorb the incident light L to emit light having a wavelength that is different from a wavelength of the incident light L. In one or more embodiments, the first wavelength conversion particle QD1 may absorb the incident light L to emit green light. However, the present disclosure is not limited thereto. For example, the first wavelength conversion particle QD1 may absorb the incident light L and may emit red light.

A transmission layer TL may be located inside the second opening OP2. That is, the transmission layer TL may overlap the second pixel area PX2, the third pixel area PX3, and the non-light-emitting area BA located between the second pixel area PX2 and the third pixel area PX3.

For example, the transmission layer TL may include a second resin part RS2 and a second scatterer SP2. The second resin part RS2 may be substantially the same as the first resin part RS1. In one or more embodiments, the transmission layer TL may be formed by an inkjet process. However, this present disclosure is not limited to this, and in one or more other embodiments, the transmission layer TL may be formed through a photolithography process.

The second scatterer SP2 may increase light path by scattering incident light L without substantially converting a wavelength of the incident light L incident on the transmission layer TL. In one or more embodiments, the second scatterer SP2 may include a metal oxide or an organic material. In one or more embodiments, the second scatterer SP2 may include titanium dioxide (TiO₂).

A second color conversion layer CT2 may be located inside the third opening OP3. That is, the second color conversion layer CT2 may overlap the fourth pixel area PX4. For example, the second color conversion layer CT2 may include a third resin part RS3, a third scatterer SP3, and a second wavelength conversion particle QD2. The third resin part RS3 may be substantially the same as the first resin part RS1. In one or more embodiments, the second color conversion layer CT2 may be formed through an inkjet process.

The third scatterer SP3 may increase a light path by scattering incident light L without substantially converting a wavelength of the incident light L incident on the second color conversion layer CT2. In one or more embodiments, the third scatterer SP3 may include a metal oxide or an organic material. In one or more embodiments, the third scatterer SP3 may include titanium dioxide (TiO₂).

The second wavelength conversion particle QD2 may include quantum dot. The quantum dot may absorb the incident light L to emit light having a wavelength that is different from a wavelength of the incident light L. In one or more embodiments, the second wavelength conversion particle QD2 may absorb the incident light L, and may emit red light. However, the present disclosure is not limited thereto. For example, the second wavelength conversion particle QD2 may absorb the incident light L, and may emit the green light.

In one or more embodiments, the incident light L emitted from each of the first light-emitting element LED1, the second light-emitting element LED2, the third light-emitting element LED3, and the fourth light-emitting elements LED4 may be blue light. However, the present disclosure is not limited to this, and in one or more other embodiments, the incident light L from each of the first light-emitting element LED1, the second light-emitting element LED2, the third light-emitting element LED3, and the fourth light-emitting elements LED4 may be light of different colors from blue light.

The color filter 200 may include a second base substrate SUB2, a color filter layer CF, a low refractive layer LR, and a black matrix layer BM.

For example, the color filter layer CF may include a first color filter CF1, a second color filter CF2, and a third color filter CF3.

The second base substrate SUB2 may include a transparent material. Examples of materials that may be used as the second base substrate SUB2 may include glass, plastic, or the like. A surface of the second base substrate SUB2 facing the first base substrate SUB1 may be defined as a lower surface.

The black matrix layer BM may be located under the lower surface of the second base substrate SUB2. The black matrix layer BM may define a first cutout portion COP1, a second cutout portion COP2, a third cutout portion COP3, and a fourth cutout portion COP4 in a portion overlapping the first pixel area PX1, the second pixel area PX2, the third pixel area PX3, and the fourth pixel area PX4, respectively. That is, the black matrix layer BM may entirely overlap the non-light-emitting area BA.

In one or more embodiments, the black matrix layer BM may include an opaque metal, such as chromium (Cr) or chromium oxide (CrOₓ). The black matrix layer BM may include a black resin that absorbs light. In one or more embodiments, the black matrix layer BM may be formed through a photolithography process.

A first color filter CF1 may be located inside the first cutout portion COP1. That is, the first color filter CF1 may overlap the first pixel area PX1. For example, the first color filter CF1 may transmit green light.

In one or more embodiments, the first color filter CF1 may overlap the non-light-emitting area BA. That is, the first color filter CF1 may overlap the first pixel area PX1 and the non-light-emitting area BA. However, the present disclosure is not limited thereto, and in one or more other embodiments, the first color filter CF1 may overlap the first pixel area PX1, while not overlapping the non-light-emitting area BA.

The second color filter CF2 may overlap the second opening OP2. For example, the second color filter CF2 may be located inside the second cutout portion COP2 and the third cutout portion COP3. That is, the second color filter CF2 may overlap the second pixel area PX2 and the third pixel area PX3. In one or more embodiments, the second color filter CF2 may transmit blue light.

In one or more embodiments, the second color filter CF2 may overlap the non-light-emitting area BA. For example, the second color filter CF2 may overlap the non-light-emitting area BA located between the first pixel area PX1 and the second pixel area PX2, and may overlap the non-light-emitting area BA located between the third pixel area PX3 and the fourth pixel area PX4. However, the present disclosure is not limited to this, and in one or more other embodiments, the second color filter CF2 may overlap the second pixel area PX2 and the third pixel area PX3, while not overlapping the non-light-emitting area BA.

A third color filter CF3 may be located inside the fourth cutout portion COP4. That is, the third color filter CF3 may overlap the fourth pixel area PX4. For example, the third color filter CF3 may transmit red light.

In one or more embodiments, the third color filter CF3 may overlap the non-light-emitting area BA. That is, the third color filter CF3 may overlap the fourth pixel area PX4 and the non-light-emitting area BA. However, the present disclosure is not limited thereto, and in one or more other embodiments, the third color filter CF3 may overlap the fourth pixel area PX4, while not overlapping the non-light-emitting area BA.

The low refractive layer LR may be located under the color filter layer CF. In one or more embodiments, the low refractive layer LR may include an organic material. The low refractive layer LR may increase the luminance, and may increase a lifespan of the display device DD, by improving light extraction efficiency.

A column spacer may be located between the display 100 and the color filter 200. Through the column spacer, a gap between the display 100 and the color filter 200 may be maintained. However, for convenience of description, the column spacer is omitted in the present specification.

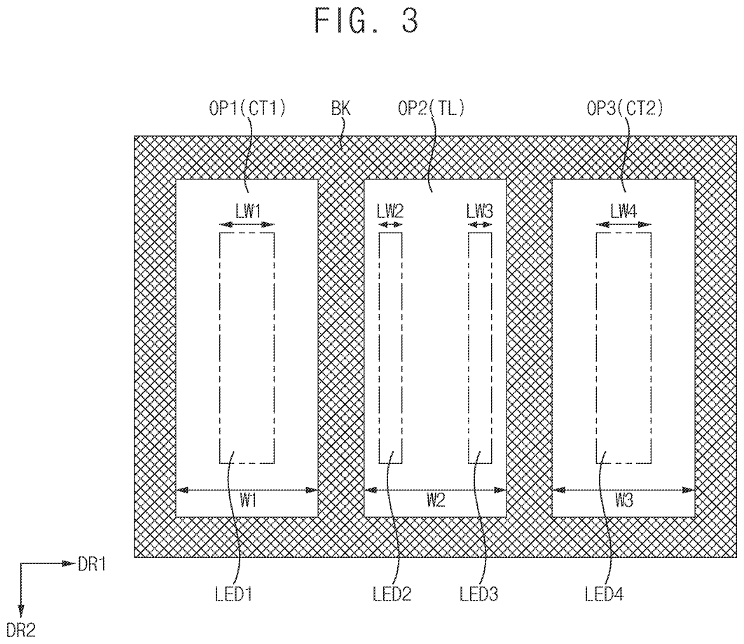

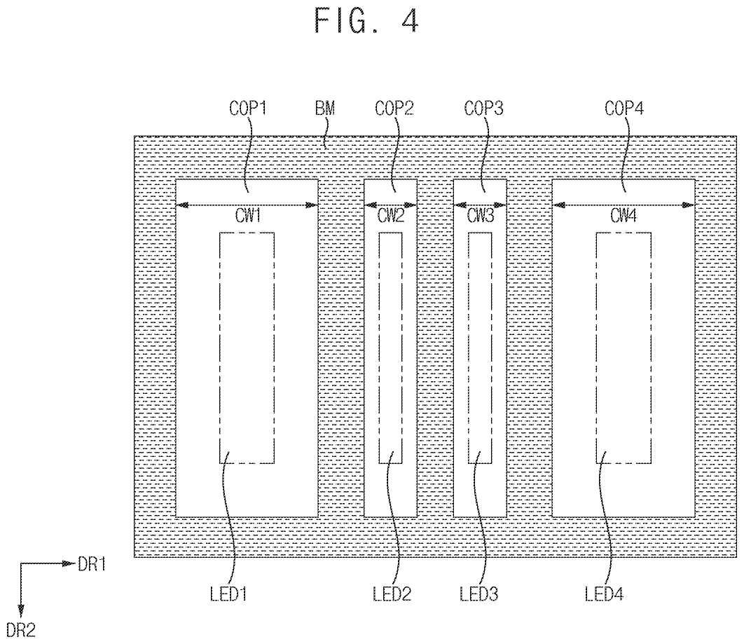

FIG. 3 is a schematic plan view illustrating a bank layer included in the display device of FIG. 1. FIG. 4 is a schematic plan view illustrating a black matrix layer included in the display device of FIG. 1.

Referring to FIGS. 2 and 3, in one or more embodiments, a width W1 of the first opening OP1 may be the same as, or similar to, a width W2 of the second opening OP2. For example, the width W1 of the first opening OP1 in the first direction DR1 may be the same as, or similar to, the width W2 of the second opening OP2 in the first direction DR1. The width W2 of the second opening OP2 may be the same as, or similar to, a width W3 of the third opening OP3.

In one or more embodiments, each of the first opening OP1, the second opening OP2, and the third opening OP3 may have a rectangular shape in a plan view. However, the present disclosure is not limited to it, and in one or more other embodiments, each of the first opening OP1, the second opening OP2, and the third opening OP3 may have a square type, a diamond type, or the like, in a plan view.

When each of the first opening OP1, the second opening OP2, and the third opening OP3 has a rectangular shape in a plan view, a color defect phenomenon of the display device DD may be reduced compared to each of the first opening OP1, the second opening OP2, and the third opening OP3 having a square shape, a diamond shape, or the like, in a plan view.

The color defect phenomenon may refer to a phenomenon in which a color other than white is displayed at a boundary if a black object is displayed on a white background, or if a white object is displayed on a black background.

In one or more embodiments, a width LW1 of the first light-emitting element LED1 may be greater than a width LW2 of the second light-emitting element LED2. The width LW1 of the first light-emitting element LED1 may be greater than a width LW3 of the third light-emitting element LED3. In one or more embodiments, the width LW2 of the second light-emitting element LED2 may be the same as, or similar to, the width LW3 of the third light-emitting element LED3. The width LW1 of the first light-emitting element LED1 may be the same as, or similar to, a width LW4 of the fourth light-emitting element LED4.

In one or more embodiments, and referring back to FIG. 2, a distance L1 between the first light-emitting element LED1 and the second light-emitting element LED2 may be greater than a distance L2 between the second light-emitting element LED2 and the third light-emitting element LED3. For example, the distance L1 in the first direction DR1 between the first light-emitting element LED1 and the second light-emitting element LED2 may be greater than the distance L2 in the first direction DR1 between the second light-emitting element LED2 and the third light-emitting element LED3.

In one or more embodiments, the distance L1 between the first light-emitting element LED1 and the second light-emitting element LED2 may be the same as, or similar to, a distance L3 between the third light-emitting element LED3 and the fourth light-emitting element LED4. For example, the distance L1 in the first direction DR1 between the first light-emitting element LED1 and the second light-emitting element LED2 may be the same as, or similar to, the distance L3 in the first direction DR1 between the third light-emitting element LED3 and the fourth light-emitting element LED4.

This is because the width W1 of the first opening OP1, the width W2 of the second opening OP2, and the width W3 of the third opening OP3 in the first direction DR1 may be the same as, or similar to, each other. That is, in a plan view, one first light-emitting element LED1 and one fourth light-emitting element LED4 may be located inside the first opening OP1 and the third opening OP3, respectively, and the second light-emitting element LED2 and the third light-emitting device LED3 may be located inside the second opening OP2.

In one or more embodiments, the distance L2 between the second light-emitting element LED2 and the third light-emitting element LED3 may be about 20 micrometers (um) or more. This is to reduce or prevent mixing between the second pixel area PX2 and the third pixel area PX3.

According to one or more embodiments, in a plan view, the second light-emitting element LED2 and third light-emitting element LED3, which are adjacent to each other, may be located in the second opening OP2 defined in the bank layer BK. Accordingly, the distance L2 between the second pixel area PX2 and the third pixel area PX3 may decrease. That is, as a plurality of light-emitting elements are located in one opening, a gap between adjacent pixel areas of the plurality of pixel areas may be narrowed. Accordingly, resolution of the display device may be improved.

Referring to FIGS. 2, 3, and 4, the black matrix layer BM may be located on (e.g., above) the bank layer BK. In one or more embodiments, a width CW1 of the first cutout portion COP1 may be greater than a width CW2 of the second cutout portion COP2. For example, the width CW1 of the first cutout portion COP1 in the first direction DR1 may be greater than the width CW2 of the second cutout portion COP2 in the first direction DR1.

The width CW1 of the first cutout portion COP1 may be greater than a width CW3 of the third cutout portion COP3. In one or more embodiments, the width CW1 of the first cutout portion COP1 may be the same as, or similar to, a width CW4 of the fourth cutout portion COP4. The width CW2 of the second cutout portion COP2 and the width CW3 of the third cutout portion COP3 may be the same as, or similar to, each other.

In one or more embodiments, each of the first cutout portion COP1, the second cutout portion COP2, the third cutout portion COP3, and the fourth cutout portion COP4 may have a rectangular shape in a plan view. However, the present disclosure is not limited thereto, and in one or more other embodiments, each of the first cutout portion COP1, the second cutout portion COP2, the third cutout portion COP3, and the fourth cutout portion COP4 may have a square shape, a diamond shape, or the like, in a plan view.

The black matrix layer BM may distinguish adjacent pixel areas of the plurality of pixel areas, or may reduce or prevent mixing between the adjacent pixel areas. For example, the black matrix layer BM may distinguish the second pixel area PX2 from the third pixel area PX3.

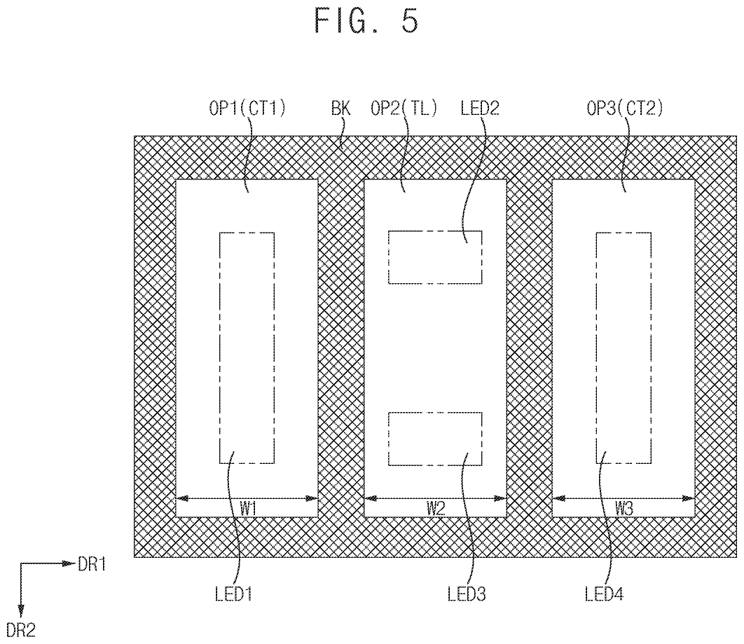

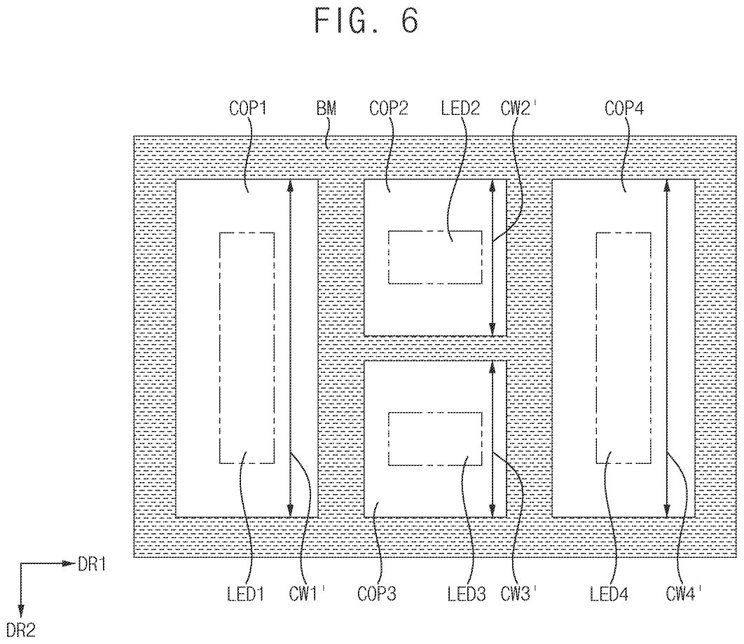

FIG. 5 is a schematic plan view illustrating a bank layer included in a display device according to one or more other embodiments. FIG. 6 is a schematic plan view illustrating a black matrix layer included in the display device according to one or more other embodiments.

In describing a display device according to one or more other embodiments in FIGS. 5 and 6, elements that are substantially the same as those of the display device DD according to one or more embodiments shown in FIGS. 2, 3 and 4 may be given the same reference numerals, and a repeated detailed description thereof may be omitted.

Referring to FIG. 5, the first light-emitting element LED1 may be located inside the first opening OP1 in a plan view. The second light-emitting element LED2 may be located inside the second opening OP2 in a plan view. That is, the second light-emitting element LED2 may be spaced apart from the first light-emitting element LED1 in the first direction DR1. The third light-emitting element LED3 may be located inside the second opening OP2 in a plan view. The third light-emitting element LED3 may be spaced apart from the second light-emitting element LED2 in the second direction DR2. The fourth light-emitting element LED4 may be located inside the third opening OP3. The fourth light-emitting element LED4 may be spaced apart from the second light-emitting element LED2 and the third light-emitting element LED3 in the first direction DR1.

Referring to FIGS. 5 and 6, the black matrix layer BM may be located on (e.g., above) the bank layer BK. In one or more embodiments, a width, or length, CW1′ of the first cutout portion COP1 in the second direction DR2 may be greater than a width/length CW2′ of the second cutout portion COP2 in the second direction DR2. The width/length CW1′ of the first cutout portion COP1 may be greater than a width/length CW3 of the third cutout portion COP3 in the second direction DR2. In one or more embodiments, the width/length CW2′ of the second cutout portion COP2 may be the same as, or similar to, the width/length CW3′ of the third cutout portion COP3. The width/length CW1′ of the first cutout portion COP1 may be the same as, or similar to, a width/length CW4′ of the fourth cutout portion COP4.

The third cutout portion COP3 of the display device DD according to one or more embodiments of FIGS. 2 and 4 may be spaced apart from the second cutout portion COP2 in the first direction DR1. On the other hand, the third cutout portion COP3 of the display device according to one or more other embodiments in FIG. 6 may be spaced apart from the second cutout portion COP2 in the second direction DR2.

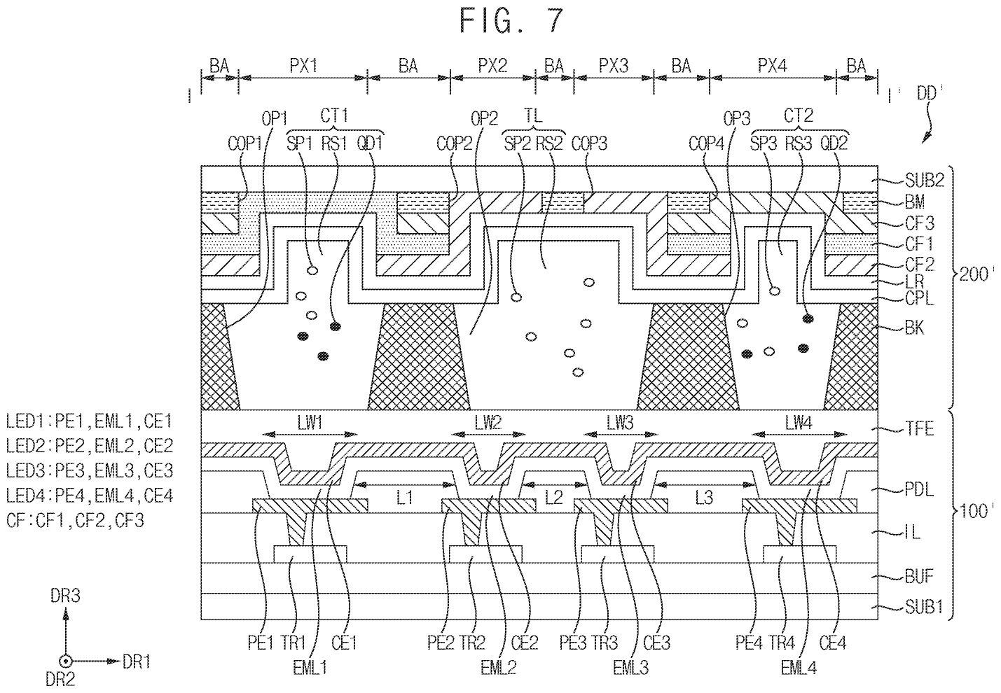

FIG. 7 is a schematic cross-sectional view illustrating a display device according to one or more other embodiments.

In describing a display device DD′ according to one or more other embodiments in FIG. 7, substantially the same elements as the display device DD according to one or more embodiments in FIGS. 2, 3, and 4 may be given the same reference numerals, and a repeated detailed description thereof may be omitted.

The display device DD′ according to one or more other embodiments in FIG. 7 may be different in arrangement of some components from the display device DD according to one or more embodiments in FIG. 2.

Referring to FIG. 7, a display device DD′ may include a display 100′ and a color filter 200′.

The display 100′ may include a first base substrate SUB1, a buffer layer BUF, an insulating layer IL, a pixel-defining layer PDL, an encapsulation layer TFE, a first pixel electrode PE1, a first light-emitting layer EML1, a first common electrode CE1, a second pixel electrode PE2, a second light-emitting layer EML2, a second common electrode CE2, a third pixel electrode PE3, a third light-emitting layer EML3, a third common electrode CE3, a fourth pixel electrode PE4, a fourth light-emitting layer EML4, a fourth common electrode CE4, a first transistor TR1, a second transistor TR2, a third transistor TR3, and a fourth transistor TR4.

The buffer layer BUF may be located on (e.g., above) the first base substrate SUB1. The first transistor TR1, the second transistor TR2, the third transistor TR3, and the fourth transistor TR4 may be located on (e.g., above) the buffer layer BUF. The insulating layer IL may be located on (e.g., above) the buffer layer BUF. The first pixel electrode PE1, the second pixel electrode PE2, the third pixel electrode PE3, and the fourth pixel electrode PE4 may be located at portions overlapping the first pixel area PX1, the second pixel area PX2, the third pixel area PX3, and the fourth pixel area PX4 on the insulating layer IL, respectively.

The pixel-defining layer PDL may be located on (e.g., above) the insulating layer IL, the first pixel electrode PE1, the second pixel electrode PE2, the third pixel electrode PE3, and the fourth pixel electrode PE4. The pixel-defining layer PDL may overlap the non-light-emitting area BA.

A light-emitting layer may be located on (e.g., above) the first pixel electrode PE1, the second pixel electrode PE2, the third pixel electrode PE3, the fourth pixel electrode PE4, and the pixel-defining layer PDL. The light-emitting layer may include the first light-emitting layer EML1, the second light-emitting layer EML2, the third light-emitting layer EML3, and the fourth light-emitting layer EML4. A common electrode may be located on (e.g., above) the light-emitting layer. The common electrode may include the first common electrode CE1, the second common electrode CE2, the third common electrode CE3, and the fourth common electrode CE4.

The first pixel electrode PE1, the first light-emitting layer EML1, and the first common electrode CE1 may constitute a first light-emitting element LED1. The second pixel electrode PE2, the second light-emitting layer EML2, and the second common electrode CE2 may constitute a second light-emitting element LED2. The third pixel electrode PE3, the third light-emitting layer EML3, and the third common electrode CE3 may constitute a third light-emitting element LED3. The fourth pixel electrode PE4, the fourth light-emitting layer EML4, and the fourth common electrode CE4 may constitute a fourth light-emitting element LED4.

The encapsulation layer TFE may be located on (e.g., above) the first common electrode CE1, the second common electrode CE2, the third common electrode CE3, and the fourth common electrode CE4.

The color filter 200′ may include a color filter layer CF, a second base substrate SUB2, a low refractive layer LR, a capping layer CPL, a bank layer BK, and a black matrix layer BM.

The black matrix layer BM may be located under the second base substrate SUB2. The black matrix layer BM may define a first cutout portion COP1, a second cutout portion COP2, a third cutout portion COP3, and a fourth cutout portion COP4 in a portion overlapping the first pixel area PX1, the second pixel area PX2, the third pixel area PX3, and the fourth pixel area PX4, respectively. That is, the black matrix layer BM may entirely overlap the non-light-emitting area BA.

A first color filter CF1 may be located inside the first cutout portion COP1. That is, the first color filter CF1 may overlap the first pixel area PX1. For example, the first color filter CF1 may transmit green light.

In one or more embodiments, the first color filter CF1 may overlap the non-light-emitting area BA. That is, the first color filter CF1 may overlap the first pixel area PX1 and the non-light-emitting area BA. However, the present disclosure is not limited thereto, and in one or more other embodiments, the first color filter CF1 may overlap the first pixel area PX1, while not overlapping the non-light-emitting area BA.

The second color filter CF2 may overlap the second opening OP2. For example, the second color filter CF2 may be located inside the second cutout portion COP2 and the third cutout portion COP3. That is, the second color filter CF2 may overlap the second pixel area PX2 and the third pixel area PX3. In one or more embodiments, the second color filter CF2 may transmit blue light.

In one or more embodiments, the second color filter CF2 may overlap the non-light-emitting area BA. For example, the second color filter CF2 may overlap the non-light-emitting area BA located between the non-light-emitting area BA and the first pixel area PX1 and the second pixel area PX2, and may be located between the third pixel area PX3 and the fourth pixel area PX4. However, the present disclosure is not limited to this, and in one or more other embodiments, the second color filter CF2 may overlap the second pixel area PX2 and the third pixel area PX3, while not overlapping the non-light-emitting area BA.

A third color filter CF3 may be located inside the fourth cutout portion COP4. That is, the third color filter CF3 may overlap the fourth pixel area PX4. For example, the third color filter CF3 may transmit red light.

In one or more embodiments, the third color filter CF3 may overlap the non-light-emitting area BA. That is, the third color filter CF3 may overlap the fourth pixel area PX4 and the non-light-emitting area BA. However, the present disclosure is not limited thereto, and in one or more other embodiments, the third color filter CF3 may overlap the fourth pixel area PX4, while not overlapping the non-light-emitting area BA.

The low refractive layer LR may be located under the color filter layer CF. The capping layer CPL may be located under the low refractive layer LR.

The bank layer BK may be located under the capping layer CPL. The bank layer BK may define a first opening OP1 in a portion overlapping the first pixel area PX1. That is, the bank layer BK may define the first opening OP1 in a portion overlapping the first light-emitting element LED1.

The bank layer BK may define a second opening OP2 in a portion overlapping the second pixel area PX2, the third pixel area PX3, and the non-light-emitting area BA. The non-light-emitting area BA may be located between the second pixel area PX2 and the third pixel area PX3. That is, the bank layer BK may define the second opening OP2 in a portion overlapping the second light-emitting element LED2, the third light-emitting element LED3, and the pixel-defining layer PDL. The pixel-defining layer PDL may be located between the second light-emitting element LED2 and the third light-emitting element LED3.

The bank layer BK may define a third opening OP3 in a portion overlapping the fourth pixel area PX4. That is, the bank layer BK may define the third opening OP3 in a portion overlapping the fourth light-emitting element LED4.

A first color conversion layer CT1 may be located inside the first opening OP1. That is, the first color conversion layer CT1 may overlap the first pixel area PX1. For example, the first color conversion layer CT1 may include a first resin part RS1, a first scatterer SP1, and a first wavelength conversion particle QD1.

A transmission layer TL may be located inside the second opening OP2. That is, the transmission layer TL may overlap the second pixel area PX2, the third pixel area PX3, and the non-light-emitting area BA located between the second pixel area PX2 and the third pixel area PX3. For example, the transmission layer TL may include a second resin part RS2 and a second scatterer SP2.

A second color conversion layer CT2 may be located inside the third opening OP3. That is, the second color conversion layer CT2 may overlap the fourth pixel area PX4. For example, the second color conversion layer CT2 may include a third resin part RS3, a third scatterer SP3, and a second wavelength conversion particle QD2.

The present disclosure can be applied to various display devices. For example, the present disclosure is applicable to various display devices, such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the embodiments disclosed, and that modifications to the disclosed embodiments, as well as other embodiments, are intended to be included within the scope of the appended claims, with functional equivalents thereof to be included therein.

What is claimed is:

1. A display device comprising:
a first base substrate;
a second base substrate facing the first base substrate;
a first light-emitting element above the first base substrate;
a second light-emitting element above the first base substrate;
a third light-emitting element above the first base substrate;
a pixel-defining layer above the first base substrate, and between the second light-emitting element and the third light-emitting element;
a bank layer under the second base substrate, and defining a first opening overlapping the first light-emitting element, and a second opening overlapping the second light-emitting element, the third light-emitting element, and the pixel-defining layer; and
a transmission layer inside the second opening.

2. The display device of claim 1, further comprising a black matrix layer between the second base substrate and the bank layer, and defining a first cutout portion, a second cutout portion, and a third cutout portion overlapping the first light-emitting element, the second light-emitting element, and the third light-emitting element, respectively.

3. The display device of claim 2, wherein a width of the first cutout portion is greater than a width of the second cutout portion and a width of the third cutout portion.

4. The display device of claim 2, wherein the first cutout portion, the second cutout portion, and the third cutout portion have a rectangular shape in a plan view.

5. The display device of claim 1, further comprising a color filter layer comprising a first color filter and a second color filter between the second base substrate and the bank layer.

6. The display device of claim 5, wherein the second color filter overlaps the second opening, and is configured to transmit blue light.

7. The display device of claim 1, wherein a width of the first light-emitting element is greater than a width of the second light-emitting element and a width of the third light-emitting element.

8. The display device of claim 1, wherein a distance between the first light-emitting element and the second light-emitting element is greater than a distance between the second light-emitting element and the third light-emitting element.

9. The display device of claim 1, wherein the first opening and the second opening have a rectangular shape in a plan view.

10. The display device of claim 1, further comprising a color conversion layer comprising scatterer and wavelength conversion particle filling the first opening.

11. A display device comprising:
a first base substrate;
a second base substrate facing the first base substrate;
a first light-emitting element above the first base substrate;
a second light-emitting element above the first base substrate, and spaced apart from the first light-emitting element in a first direction;
a third light-emitting element above the first base substrate, and spaced apart from the second light-emitting element in a second direction crossing the first direction;
a pixel-defining layer above the first base substrate, and between the second light-emitting element and the third light-emitting element;
a bank layer under the second base substrate, and defining a first opening overlapping the first light-emitting element, and a second opening overlapping the second light-emitting element, the third light-emitting element, and the pixel-defining layer; and
a transmission layer inside the second opening.

12. The display device of claim 11, further comprising a black matrix layer between the second base substrate and the bank layer, and defining a first cutout portion, a second cutout portion, and a third cutout portion overlapping the first light-emitting element, the second light-emitting element, and the third light-emitting element, respectively.

13. The display device of claim 12, wherein a width of the first cutout portion in the second direction is greater than a width of the second cutout portion in the second direction and a width of the third cutout portion in the second direction.

14. The display device of claim 13, wherein the first cutout portion, the second cutout portion, and the third cutout portion have a rectangular shape in a plan view.

15. The display device of claim 11, further comprising a color filter layer comprising a first color filter and a second color filter between the second base substrate and the bank layer.

16. The display device of claim 15, wherein the second color filter overlaps the second opening, and is configured to transmit blue light.

17. The display device of claim 11, wherein a width of the first light-emitting element is greater than a width of the second light-emitting element and a width of the third light-emitting element.

18. The display device of claim 11, wherein a distance between the first light-emitting element and the second light-emitting element is greater than a distance between the second light-emitting element and the third light-emitting element.

19. The display device of claim 11, wherein the first opening and the second opening have a rectangular shape in a plan view.

20. The display device of claim 11, further comprising a color conversion layer comprising scatterer and wavelength conversion particle filling the first opening.
